(19) United States
(12) Patent Application Publication
(10) Pub. No.: US 2005/0169406 A1
(43) Pub. Date: Aug. 4, 2005

(54) Receiver for optical or electromagnetic signals with iterative equalization and error correction plus a method for improving the exactness in relating binary data to a digitalized -data transmitting, analog electromagnetic or optical-electrical signal

(75) Inventor: Fred Buchali, Waiblingen (DE)

Correspondence Address: SUGHRUE MION, PLLC, 2100 PENNSYLVANIA AVENUE, N.W., SUITE 800, WASHINGTON, DC, 20037, US

(73) Assignee: ALCATEL

(21) Appl. No.: 10/991,488

(22) Filed: Nov. 19, 2004

(30) Foreign Application Priority Data
Jan. 30, 2004 (EP) 04 290 236.1

(51) Int. Cl. H03K 5/159

(52) U.S. Cl. 375/341

(57) ABSTRACT

A receiver is described for optical or electromagnetic signals comprising a digital equalizer and a Forward Error Correction, said digital equalizer and FEC combined together to obtain an iterative equalization and error-correction loop, plus a method is described for improving the exactness in relating binary data to a digitalized-data transmitting, analog electromagnetic or optical-electrical signal arriving at a receiver, comprising the steps a) transforming the arriving analog signals into analog signals in the form of digital soft data representing interim values, which indicate the value of the amplitude of the analog signal, b) feeding the soft data to a digital equalizer, c) sequential determination of the interim value representing the boundary at which the decision would have to be made whether a ‘0’ or a ‘1’ had to be related to the soft data when transformed to binary data in the digital equalizer, d) feeding the soft-data signal further processed in the way described to a soft-in/soft-out FEC, e) error correction of the soft data by means of the check bits contained in the signal, f) removal of the check bits, g) output of the error-corrected signal in the form of soft data, h) preprocessing the signal for reinjection into a digital equalizer, i) feeding back the signal to the digital equalizer placed in the signal path, and k) repeating steps c) to j) until no further improvement of the data quality can be detected or until a predefined number of iteration loops have been executed, and l) hard decision and transformation of the soft data preprocessed in the way described into binary data.

### TECHNICAL FIELD

The invention describes a receiver for a digitalized-data transmitting, optical or electromagnetic signal with a digital equalizer/Forward Error Correction (FEC) setup with an iterative equalization and error-correction loop. By repeatedly running the loop, the efficiency of a digital equalizer, especially a Viterbi Equalizer, in combination with an FEC can be optimized. The invention is based on a priority application EP 04 290 236.1 which is hereby incorporated by reference.

### BACKGROUND OF THE INVENTION

The invention relates to a receiver for optical or electromagnetic signals comprising a digital equalizer and a Forward Error Correction, wherein said digital equalizer and Forward Error Correction are combined together to obtain an iterative equalization and error-correction loop and to a method for improving the exactness in relating binary data to a digitalized-data transmitting, analog electromagnetic or optical-electrical signal arriving at a receiver.

When digital data are to be transmitted by means of an analog electromagnetic or optical signal, the problem occurs that when the signal arrives at a receiver at the end of the transmission path, due to interferences and losses along the transmission path, the digital data cannot be related as unambiguously to the analog signal anymore as it was possible when the signal was injected into the transmission path. Especially in the case of broadband signals that are to be transmitted along a long transmission path, the quality of the digital signal is noticeably reduced due to the noise that gets more and more as the distance grows. By improving the receiver's ability to identify digital data transmitted by the analog signal, leading to a reduced number of amplifiers along the transmission path, costs can be reduced and the error rate of the data received can be lowered. Improvements of the receivers are limited to the improvement of the algorithms used for digital equalization after the analog-to-digital conversion.

In this context, special attention is given to so-called Viterbi equalizers, which are digital electronic equalizers with lowest error rates or often highest efficiency, that can be used for treating distorted signals. They are applied in combination with Forward Error Correction (FEC). Both must reduce the signal-to-noise ratio to an absolute minimum. Such a combination is still not well-controlled for high transmission rates in the range of 10 to 40 Gbit/s and higher of optical signals. Next-generation 10 and 40 Gbit/s data transmission systems are operated close to the noise limit without spending much margins for transmission impairments. An efficient mitigation of these impairments is mandatory to meet the needs of these systems.

The known combination of Viterbi equalizer and FEC is not sufficient to achieve an efficient mitigation of these impairments, so as to ensure that an acceptable maximum error rate during data transmission in next-generation data transmission systems is not exceeded.

### TECHNICAL PURPOSE OF THE INVENTION

The technical purpose of the invention is to develop a receiver capable of reducing the signal-to-noise ratio necessary for unambiguously identifying digital data transmited by means of an electromagnetic or optical signal to an absolute minimum, and capable of identifying digital data also in signals heavily corrupted by additive noise and distortions, and to develop a method for enabling such an unambiguous identification for signals with a minimum signal-to-noise ratio.

### DISCLOSURE OF THE INVENTION AND ITS ADVANTAGES

The first part of the invention's technical purpose is fully met by said receiver of said specifying features of claim 1, wherein the receiver is characterized in that said digital equalizer and Forward Error Correction are combined together to obtain an iterative equalization and error-correction loop.

The proposed solution is based on an iteration where the data are equalized and error-corrected and coded in each iteration loop. In order to achieve additional coding/equalization gain, it is mandatory to apply an iterative setup which outperforms combinations of optical and electronical means.

The soft data outputted by an analog-to-digital converter (ADC) is being fed in a usual way to a digital equalizer and subsequently to a Forward Error Correction (FEC). An elementary difference compared to the state-of-the-art results from the fact that the signal outputted by the digital equalizer to the FEC and subsequently outputted by the FEC consists of soft data. By generating a soft-data output signal in the FEC, the output signal can be fed to the digital equalizer again. This procedure can basically be iterated at will, however, due to practical reasons, the procedure is being terminated after a predefined number of iterations or after the output signal has achieved the desired quality.

Exactly like in a sender, the signal outputted by the FEC, comprising no check bits, is being fed to a FEC-coding apparatus, which adds the check bits eliminated in the FEC to the signal again. The output signal is then fed to a distortion-coding apparatus, which equips the signal again with the original channel coding equalized by the digital equalizer, e.g. a Viterbi equalizer. By repeatedly running the loop, the efficiency of the equalizer as well as the FEC can be optimized. By this, an application in systems which are operated close to the noise limit is possible. The iterative equalization and error correction lead to drastically reduced minimum optical-signal-to-noise ratio values, thereby improving the system budget. The procedure works as follows: On the receiver side, an analog signal, e.g. an optical signal, is fed to an ADC. Each amplitude corresponds to a digital signal in the form of ‘1’ or ‘0’. The ADC transforms the analog signal in digital soft data. The soft data comprises groups of bits, each corresponding to an analogue amplitude. By transforming the analog input signal into bit groups of a soft-data output signal, the value of the amplitude of the analogue signal can be digitally captured and used for making a hard decision, i.e. relating the analog signal to a digital value in the form of ‘1’ or ‘0’. The digital equalizer used for the iterative equalization and the error-correction loop is a soft-in/soft-out digital equalizer, which is capable of processing and outputting soft data. The soft data outputted by the digital equalizer is being fed to a modified FEC which is capable of both processing and outputting soft data. According to the state of the art, FECs are exclusively used for processing binary data, i.e. ‘hard’ data, which, unlike soft data, comprise no interim values as additional information. Since the FEC outputs soft data, it is now possible to feed this output signal to the digital equalizer, after the output signal has been preprocessed again the way it has been preprocessed prior to the digital-analog conversion on the sender side. By repeatedly running this loop, consisting of digital equalizer, FEC and signal preprocessing, the identification of the bits can be improved and the error rate can be reduced, before, following a predefined number of iterations, the soft-data signal is fed to a hard-decision device, which relates bit values to the soft data in the form of ‘1’ and ‘0’. By doing so, the signal-to-noise ratio and optical signal-to-noise ratio, respectively, necessary for unambiguously identifying digital data transmitted by means of an electromagnetic or optical signal, can be reduced to an absolute minimum.

In a preferred embodiment of said receiver, the iteration loop is set up such that the FEC is connected to the output of the equalizer, with the equalizer itself being connected to the output of the FEC.

In a preferred embodiment of said receiver, the digital equalizer used is a Viterbi equalizer. The iteration loop is made out of a Viterbi equalizer and a FEC decoder, with the Viterbi equalizer being modified compared to the state of the art such that it is capable of outputting soft data instead of binary data. The Viterbi equalizer submits said soft data instead of binary data to the FEC and the FEC corrects the errors in the soft data. The data outputted by the FEC are also soft data and are being fed back to the Viterbi equalizer, with a FEC-coding apparatus and a distortion-coding apparatus placed in the feedback path leading back from the FEC's output to the Viterbi equalizer's input. The arrangement of the FEC-coding apparatus and the distortion-coding apparatus may correspond with a part of the structure of a sender for injecting digitalized-data transmitting optical or electromagnetic signals into a transmission path.

In another preferred embodiment of said receiver, in front of the ADC an analog equalizer is placed in the signal path leading to the error-correction loop consisting of the digital equalizer, the FEC and the feedback path.

In an additional preferred embodiment of said receiver, the analog equalizer is an optical equalizer, for example placed between the demultiplexer and the optical-electrical converter.

The second part of the invention's technical purpose is fully met by said method for improving the exactness in relating binary data to a digitalized-data transmitting, analog electromagnetic or optical signal arriving at a receiver, comprising the steps of
a) transforming the arriving analog signals into digital soft data representing interim values, which indicate the value of the amplitude of the analog signal,
b) feeding the soft data to a digital equalizer,
c) sequential determination of the interim value representing the boundary at which the decision would have to be made whether a ‘0’ or a ‘1’ had to be related to the soft data when transformed to binary data in the digital equalizer,
d) feeding the soft-data signal further processed in the way described to a soft-in/soft-out FEC,
e) error correction of the soft data in the FEC by means of the check bits contained in the signal,
f) removal of the check bits in the FEC,
g) output of the error-corrected signal by the FEC as soft data,
h) preprocessing the signal for reinjection into a digital equalizer, e.g. by adding check bits by a FEC coder and installing a channel coding by a distortion coder, wherein the FEC coder is synchronized by the FEC decoder and the distortion coder is controlled by the digital equalizer by using channel estimations provided by the Viterbi equalizer,
i) feeding back the signal to the digital equalizer placed in the signal path, and
k) repeating steps c) to j) until no further improvement of the data quality can be detected or until a predefined number of iteration loops have been executed, and
l) hard decision and transformation of the soft data preprocessed in the way described into binary data, e.g. in a hard-decision device.

In a preferred embodiment of said method, the digital equalizer is a soft-in/soft-out Viterbi equalizer.

### BRIEF DESCRIPTION OF THE DRAWINGS

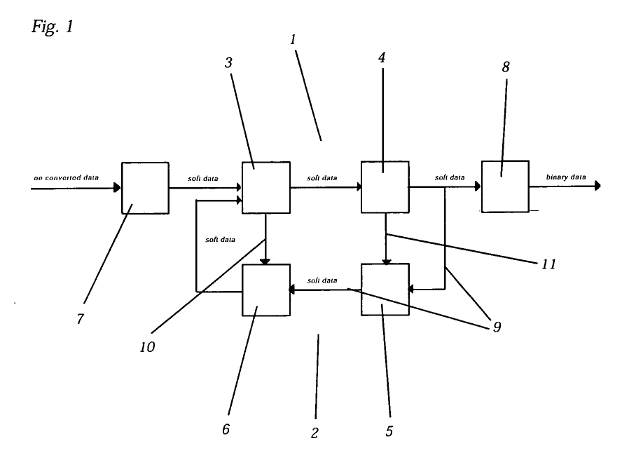

A receiver 1 as shown in FIG. 1 consists of an iteration loop 2 comprising a Viterbi equalizer 3 and a FEC decoder 4. The Viterbi equalizer 3 feeds soft data instead of binary data to the FEC decoder 4 and the FEC decoder 4 corrects the errors. The FEC decoder 4 outputs corrected soft data which are coded in the iteration loop 2 in the FEC coder 5 and in the distortion coder 6 before being fed back to the Viterbi equalizer 3, wherein the FEC coder 5 is synchronized 11 by the FEC decoder 4. FEC coder 5 and distortion coder 6 are placed in the feedback path 9 of the iteration loop 2, wherein the distortion coder 6 is controlled 10 by the Viterbi equalizer 3 by using channel estimations provided by the Viterbi equalizer 3. The Viterbi equalizer 3 considers the distortion as coding and the equalization is based on a channel model. For the subsequent iteration loop a coding according to the channel model is mandatory.

### DETAILED DESCRIPTION OF PREFERRED EMBODIMENTS

An analog signal, e.g. an optical signal, is being fed to an ADC 7 on the receiver side. Each amplitude corresponds to a digital signal in form of ‘1’ or ‘0’. The ADC 7 transforms the analog signal in digital soft data. The soft data comprises groups of bits, each corresponding to the value of the related analog amplitude. By transforming the analog input signal into bit groups of a soft-data output signal, the value of the amplitude of the analog signal can be digitally captured and used for making a hard decision, i.e. relating the analog signal to a digital value in the form of ‘1’ or ‘0’. The Viterbi equalizer 3 used for the iteration loop 2 is a soft-in/soft-out Viterbi equalizer, which is capable of processing and outputting soft data. The soft data outputted by the Viterbi equalizer 3 is being fed to a modified FEC decoder 4 which is capable of both processing and outputting soft data. According to the state of the art, FECs are exclusively used for processing binary data, i.e. ‘hard’ data, which, unlike soft data, comprise no interim values as additional information. Since the FEC decoder 4 outputs soft data, it is now possible to feed this output signal to the Viterbi equalizer 3, after the output signal has been preprocessed again the way it has been preprocessed prior to the digital-analog conversion on the sender side. By repeatedly running this loop 2, consisting of Viterbi equalizer 3, FEC decoder 4 and signal preprocessing by means of FEC coder 5 and distortion coder 6, the identification of the bits can be improved and the error rate can be reduced, before, following a predefined number of iterations in the interation loop 2, the soft-data signal is fed to a hard-decision device 8, which relates bit values to the soft data in the form of ‘1’ and ‘0’.

Commercial Applicability:

The invention is commercially applicable particularly in the field of production and operation of networks for optical and/or electromagnetic data transmission.

List of Reference Numerals:

1 receiver
2 iteration loop
3 Viterbi equalizer
4 Forward Error Correction decoder (FEC decoder)
5 Forward Error Correction coder (FEC coder)
6 distortion coder
7 Analog-to-Digital Converter (ADC)
8 Hard-Decision Device
9 feedback path
10 control
11 synchronisation

1. Receiver for optical or electromagnetic signals comprising a digital equalizer and a Forward Error Correction, wherein said digital equalizer and Forward Error Correction are combined together to obtain an iterative equalization and error-correction loop.

2. Receiver according to claim 1, wherein the iteration loop is set up such that Forward Error Correction is connected to the output of the digital equalizer, which itself is connected to the output of the Forward Error Correction.

3. Receiver according to claim 1, wherein the digital equalizer used is a Viterbi equalizer.

4. Receiver according to claim 1, wherein in front of the analog-to-digital converter an analog equalizer is placed in the signal path leading to the iteration loop consisting of the digital equalizer, the Forward Error Correction and the feedback path.

5. Receiver according to claim 4, wherein the analog equalizer is an optical equalizer.

6. Method for improving the exactness in relating binary data to a digitalized-data transmitting, analog electromagnetic or optical-electrical signal arriving at a receiver, whereby
a) transforming the arriving analog signals into digital soft data representing interim values, which indicate the value of the amplitude of the analog signal,
b) feeding the soft data to a digital equalizer,
c) sequential determination of the interim value representing the boundary at which the decision would have to be made whether a ‘0’ or a ‘1’ had to be related to the soft data when transformed to binary data in the digital equalizer,
d) feeding the soft-data signal further processed in the way described to a soft-in/soft-out Forward Error Correction,
e) error correction of the soft data by means of the check bits contained in the signal,
f) removal of the check bits,
g) output of the error-corrected signal in the form of soft data,
h) preprocessing the signal for reinjection into a digital equalizer,
i) feeding back the signal to the digital equalizer placed in the signal path, and
k) repeating steps c) to j) until no further improvement of the data quality can be detected or until a predefined number of iteration loops have been executed, and
l) hard decision and transformation of the soft data preprocessed in the way described into binary data.

7. Method according to claim 6, wherein the digital equalizer is a soft-in/soft-out Viterbi equalizer.
